(19) United States
(12) Patent Application Publication
(10) Pub. No.: US 2025/0234532 A1
(43) Pub. Date: Jul. 17, 2025

(54) ONE-TIME PROGRAMMABLE CELL AND RELATED METHODS

(71) Applicant: Infineon Technologies AG, Neubiberg (DE)

(72) Inventors: Thorsten Meyer, München (DE); Robert Zink, Wernberg (AT); Sven Gustav Lanzerstorfer, Feldkirchen (AT); Nikolaos Hatzopoulos, Dresden (DE); Stephan Riedel, Dresden (DE)

(21) Appl. No.: 19/018,371

(22) Filed: Jan. 13, 2025

(30) Foreign Application Priority Data
Jan. 17, 2024 (DE) 102024200382.4

(51) Int. Cl. H10B 20/25

(52) U.S. Cl. CPC H10B 20/25

(57) ABSTRACT

The application relates to a one-time programmable (otp) cell, including a selector device with a channel region, an otp capacitor with an otp capacitor dielectric associated with the selector device, and an isolation dielectric having an isolation dielectric thickness. The otp capacitor dielectric includes a first dielectric in a first area and a second dielectric in a second area. The second dielectric has a second thickness which is smaller than the isolation dielectric thickness. The first dielectric has a first thickness which is smaller than the second thickness. The first area is embedded into the second area.

### TECHNICAL FIELD

The present application relates to a one-time programmable cell.

### BACKGROUND

A one-time programmable (otp) cell may be considered as a non-volatile memory cell. In so-called antifuse-technology, the otp cell is alterable to a conductive state. Upon programming, the state of the otp cell may be changed from not conducting to conducting, for instance in response to electric stress applied for programming, like a voltage or current pulse.

### SUMMARY

Examples of the present application are directed at a one-time programmable (otp) cell.

In an embodiment, the otp cell comprises a selector device and an otp capacitor, wherein an otp capacitor dielectric is associated with the selector device. The otp capacitor dielectric comprises a first dielectric with a first thickness t₁ and a second dielectric with a second thickness t₂, where t₁ is smaller than t₂. Further, t₂ is smaller than tᵢₛₒ, which is a thickness of an isolation dielectric. Therein, a first area with the first, namely thinner, dielectric is embedded into a second area with the second dielectric which is thicker than the first dielectric but still thinner than the isolation dielectric.

With the first area embedded into the second area and t₁<t₂, a stepped dielectric may be provided, for instance when viewed in a vertical cross-section. This can for instance improve a programming quality, e.g. increase a reliability of a dielectric breakdown when a programming pulse is applied. With the different thicknesses, t₁<t₂<tᵢₛₒ, the dielectric breakdown may be forced to happen away from an edge of the thick isolation dielectric, which can for instance increase a reproducibility (e.g. from cell to cell or lot to lot). The design may also provide for a pronounced accumulation during programming, for instance for a defined or appropriate voltage drop over the capacitor dielectric.

Further embodiments and features are provided in this description and the figures. Therein, the individual features shall be disclosed independently of a specific claim category, the disclosure relates to apparatus and device aspects, but also to method and use aspects. If for instance an otp cell manufactured in a certain way is described, this shall also be considered as a disclosure of a respective manufacturing method. In general words, an approach of this application is to provide an otp cell, for instance antifuse cell, which comprises an otp capacitor with a capacitor dielectric having different thicknesses, for instance a smaller thickness t₁ in a first area compared to a second thickness t₂ in a second area.

The first dielectric and/or second dielectric and/or isolation dielectric may be made of any insulating material, for example of silicon oxide. The isolation dielectric may surround the otp cell at least partly, for instance as seen in a vertical top view. In the exemplary embodiments, the isolation dielectric is a LOCOS oxide, e.g. obtained from a local oxidation of silicon, alternatively it may for instance be a field oxide, e.g. be arranged on a first side of a semiconductor body, or be part of a shallow trench isolation (STI), for instance be recessed with respect to the first side of the semiconductor body in a shallow trench.

The otp capacitor dielectric is associated with the selector device, for instance a control pulse, namely programming pulse, may propagate via the selector device to the otp capacitor dielectric. In detail, the control pulse may be transferred via the channel region to the otp capacitor dielectric, the selector device or channel region switched for instance into a conductive state for that purpose. In addition to the channel region, the selector device may comprise a gate region for controlling a current flow or conductivity of the channel region, for example a lateral channel below.

In the semiconductor body, the channel region of the selector device may be formed. The semiconductor body may comprise a semiconductor substrate, for instance combined with one or several epitaxial semiconductor layers. The isolation dielectric can be arranged on a first side of the semiconductor body, which may also be referred to as frontside. The otp capacitor may be arranged at the first side as well, for instance integrated with the selector device or connected in series thereto, as will be described in more detail below.

On the first side of the semiconductor body, a wiring structure can be arranged, which may comprise one or several metallization layers. For an isolation between the wiring structure and the semiconductor body, an insulating layer may be disposed vertically in between on the first side of the semiconductor body, the isolation dielectric being for instance thinner than the insulating layer.

In the otp capacitor dielectric, the first area (first dielectric) may be embedded into the second area (second dielectric). When viewed in a vertical top view, the first area may be laterally enclosed by the second area. The second area may enclose the first area for instance to all sides; in each vertical cross-section through the first dielectric, the first dielectric may merge directly into the second dielectric on both sides. The first dielectric may be enclosed by the second dielectric on all lateral sides. Independently of these details, the first and second dielectric may be arranged on the same height, for instance a common lateral plane extending through the first and second dielectric.

In an embodiment, the second dielectric merges directly into the isolation dielectric on at least one side when viewed in a vertical cross-section. The respective sectional plane goes through the first dielectric, for instance lies rather centrally in the otp capacitor dielectric, and lies parallel to a length direction of the channel region. The length direction may be the direction of current flow in the channel. The second dielectric may merge into the isolation dielectric in a step or obliquely. The at least one side, on which the second dielectric merges directly into the isolation dielectric, may for instance be the side facing away from the channel region of the selector device. In some embodiments, the second dielectric may merge directly into the isolation dielectric on both sides as viewed in a vertical cross-section parallel to the length direction.

In a vertical cross-section through the first dielectric and perpendicular to the length direction of the channel region, e.g. perpendicular to the direction of current flow in the channel, the second dielectric may merge directly into the isolation dielectric on both sides. In other words, the second dielectric may be embedded into the isolation dielectric at least in a lateral direction perpendicular to the length direction. Seen in a vertical top view, e.g. looking vertically onto the frontside or upper side of a semiconductor die comprising the otp cell, the isolation dielectric may enclose the first and second dielectric U-shaped, see FIGS. 2c/3c for illustration, or box-shaped to all sides, see FIG. 1c for illustration.

In an embodiment, the second thickness t₂ is at least 1.5 times the first thickness t₁, a further lower limit being for instance at least 2 times t₁. Possible upper limits of the second thickness t₂ can for example be not more than 20 times, 15 times, or 10 times the first thickness t₁.

In an embodiment, the isolation dielectric thickness tᵢₛₒ is at least 10 times, 15 times or 20 times the second thickness t₂, wherein possible upper limits may be 100 times, 80 times, 60 times or 50 times t₂. Comparing the thicknesses tᵢₛₒ, t₂ and t₁, a difference between t₂ and t₁ may be smaller than a difference between tᵢₛₒ and t₂. The second thickness t₂ may be in the range or equal to a gate dielectric thickness of the selector device (see in detail below), the isolation dielectric being for instance significantly thicker.

The first thickness t₁ may be at least 1.5 nm and/or at most 5 nm. The second thickness t₂ may be at least 4 nm and/or at most 30 nm. The isolation dielectric thickness tᵢₛₒ may be at least 100 nm and/or at most 900 nm.

As mentioned above, the selector device may have a gate region for controlling the current flow or conductivity of the channel region. The gate region may comprise a gate electrode and a gate dielectric, the latter capacitively coupling the gate electrode to the channel region. In an embodiment, the gate dielectric of the selector device has the same thickness like the second dielectric. It may be formed of the same material, for instance be deposited in the same process step. In other words, the second dielectric may be made of a gate oxide, for example silicon oxide.

In an embodiment, a centroid of the second area lies in the first area. This relates to a vertical top view, the centroid being the geometric center of the second area. In other words, the first area may be aligned centrally in the second area.

In an embodiment, the first area (first dielectric) is in an area ratio to the second area (second dielectric) of at least 1/100, further lower limits being for instance 3/100 and 5/100. Alternatively or in addition, the area ratio may be not more than 3/4, 1/2, 1/4 or 1/5. In detail, considering an outline of the second area, the first area may be subtracted from the area inside the outline to obtain the area of the second area (the second area has a “hole” where the first area is arranged).

In an embodiment, a first capacitor electrode of the otp capacitor is arranged below the capacitor dielectric, for instance embedded into the semiconductor body. The first capacitor electrode may be a doped region in the semiconductor body, for instance arranged at the first side of the semiconductor body. It can for example be formed in an epitaxial layer or layer system arranged on a semiconductor substrate.

In an embodiment, the channel region of the selector device reaches below the otp capacitor dielectric, for instance below the first dielectric. On the otp capacitor dielectric, a second capacitor electrode may be arranged, which also serves as a gate electrode of the selector device in an embodiment. In other words, the otp capacitor is embedded into the selector device. The integrated gate electrode/second capacitor electrode may for instance be formed in a polysilicon layer, e.g. be a polysilicon electrode.

In an embodiment, a respective selector device with the embedded otp capacitor is provided without a drain region. In other words, the body region of the selector device may serve as the first capacitor electrode, the second capacitor electrode above serving also as gate electrode.

In an alternative embodiment, the selector device comprises a drain region, for instance in addition to a source region and a body region. The channel region may be formed in the body region, e.g. laterally between the source region and the drain region. In combination with the embedded otp capacitor discussed above, the drain region of the selector device may serve as the first capacitor electrode, e.g. be arranged below the otp capacitor dielectric. The source and drain region may be of a first doping type, the body region of a second doping type. In the exemplary embodiments, the first type is n-type and the second type is p-type.

In an embodiment, a second capacitor electrode, which is arranged on the otp capacitor dielectric, and a gate electrode of the selector device are electrically isolated from each other. This may be an alternative to the embedded second capacitor electrode serving also as gate electrode. The gate and capacitor electrode electrically isolated from each other may be connected as wordline and bitline, the gate electrode of the selector device being for instance the wordline and the second capacitor electrode being for instance the bitline.

Though being electrically isolated from each other, the gate electrode of the selector device and the second capacitor electrode may be formed in the same material layer. This may for instance be a polysilicon layer, in which a polysilicon gate electrode and polysilicon capacitor electrode are formed.

In an embodiment, the selector device comprises a drift region. The drift region may be arranged aside the body region, it may for example be a depletable region. In case of a selector device having a drain region, the drift region may be made of the same doping type like the drain region, but with a lower doping concentration. The drift region may then be arranged laterally between the body region and the drain region.

In an embodiment, the isolation dielectric covers the drift region at least partly. As viewed in a vertical cross-section, the isolation dielectric may be arranged laterally between the source region/body region of the selector device and the otp capacitor. Seen in a vertical top view, the second area (second dielectric) may be embedded into a third area made of the isolation dielectric. Then, the second dielectric may merge directly into the isolation dielectric in each lateral direction.

The drain region of the selector device may serve as the first capacitor electrode, see the remarks above. In an alternative embodiment, the drain region of the selector device is arranged laterally aside the otp capacitor. The otp capacitor may be connected in series to the drain region of the selector device, for instance the first capacitor electrode connected in series to the drain region. This electrical connection may be formed in the semiconductor body, for instance via a doped region serving also as first capacitor electrode (see above), and/or in a wiring structure on the semiconductor body, for instance via a metallization layer.

An embodiment relates to a semiconductor die which comprises an otp cell. In addition, at least one of a DMOS device, a CMOS device or a bipolar device may be formed in the semiconductor die, for instance integrated in the same semiconductor body. In other words, the otp cell may for instance be integrated in a BD- or BCD-technology (bipolar, CMOS, DMOS). In an embodiment, the selector device and the DMOS device may have the same gate dielectric thickness.

In an embodiment, a method of manufacturing an otp cell or semiconductor die is provided. The method may comprise: forming the selector device; forming the otp capacitor with the otp capacitor dielectric; and forming the isolation dielectric.

Therein, the formation of the selector device and the formation of the otp capacitor may, at least to some extent, be done simultaneously. For instance, the gate electrode of the selector device and the second capacitor electrode may be made simultaneously and/or the second dielectric and a gate dielectric of the selector device may be made simultaneously and/or the first capacitor electrode and a drain region of the selector device may be made simultaneously.

In an embodiment, a method of programming a plurality of otp cells is provided. It may comprise causing a breakdown of the capacitor dielectric of at least one of the otp cells by a control pulse, e.g. programming pulse.

### BRIEF DESCRIPTION OF THE DRAWINGS

Below, the otp cell and a semiconductor die, as well as related methods, are explained in further detail by means of exemplary embodiments. Therein, the individual features can also be relevant for the disclosure in a different combination.

FIG. 1a shows a first embodiment of an otp cell in a vertical cross-section;

FIG. 1b shows a detailed view of an otp capacitor dielectric of the otp cell of FIG. 1a;

FIG. 1c shows the otp cell of FIG. 1a in a vertical top view;

FIG. 2a shows a second embodiment of an otp cell in a vertical cross-section;

FIG. 2b shows a detailed view of an otp capacitor dielectric of the otp cell of FIG. 2a, the sectional plane lying parallel to a length direction;

FIG. 2c shows the otp cell of FIG. 2a in a vertical top view;

FIG. 2d shows a detailed view of the otp capacitor dielectric of the otp cell of FIGS. 2a, c, the sectional plane lying perpendicular to the length direction;

FIG. 3a shows a third embodiment of an otp cell in a vertical cross-section;

FIG. 3b shows a detailed view of an otp capacitor dielectric of the otp cell of FIG. 3a, the sectional plane lying parallel to a length direction;

FIG. 3c shows the otp cell of FIG. 3a in a vertical top view;

FIG. 3d shows a detailed view of the otp capacitor dielectric of the otp cell of FIGS. 3a, c, the sectional plane lying perpendicular to the length direction;

FIG. 4 shows a semiconductor die with a plurality of otp cells;

FIG. 5a summarizes some manufacturing steps; and

FIG. 5b illustrates a method of using an otp cell.

### DETAILED DESCRIPTION

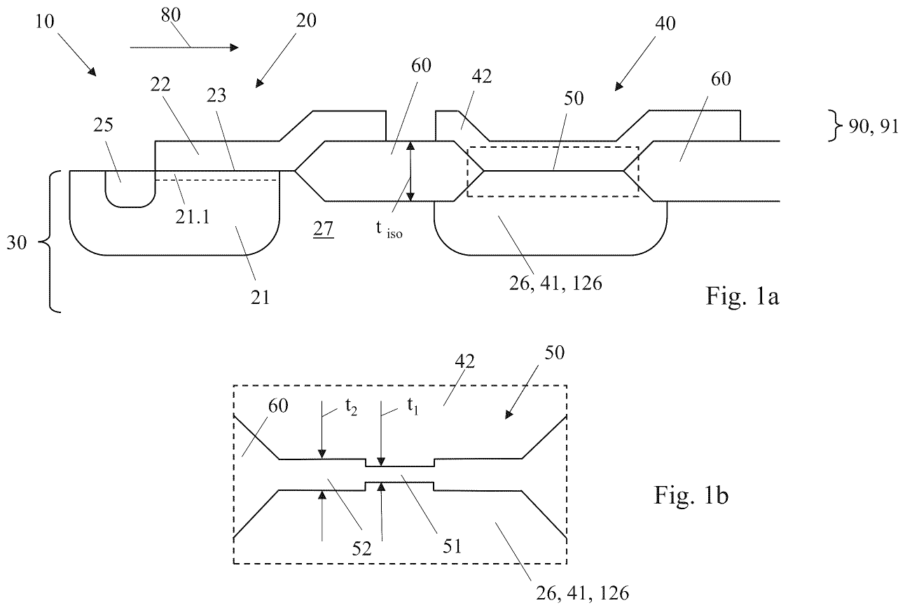

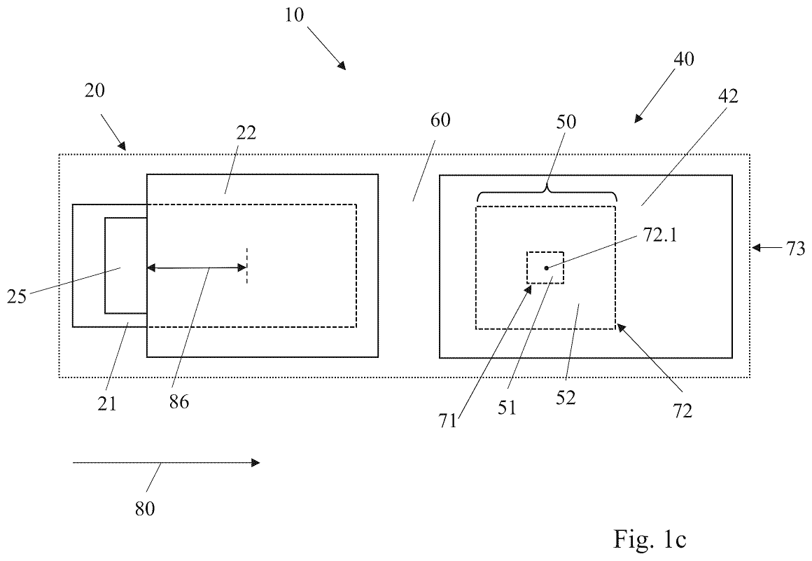

FIG. 1a shows a one-time programmable (otp) cell 10 in a vertical cross-section. The otp cell 10 comprises a selector device 20 and an otp capacitor 40. The otp capacitor 40 comprises a first capacitor electrode 41, a second capacitor electrode 42, and an otp capacitor dielectric 50 vertically between the capacitor electrodes 41, 42. For reasons of pictural representation, the otp capacitor dielectric 50 is only shown schematically in FIG. 1a and discussed in further detail with reference to FIG. 1b.

The selector device 20 of FIG. 1a comprises a source region 25, a body region 21 and a drain region 26. In addition, a drift region 27 may be arranged laterally between the body region 21 and the drain region 26. In the example shown, the source region 25, drain region 26 and drift region 27 are n-doped, the drift region 27 with a lower concentration compared to the drain region 26. In the body region 21, which is p-doped in this example, a channel region 21.1 is formed. A current flow in the channel region may be controlled via a gate electrode 22. Via a gate dielectric 23, the gate electrode 22 capacitively couples to the channel region 21.1, wherein the gate dielectric 23 is not shown as a dedicated element in further detail for the same reasons as mentioned for the otp capacitor dielectric 50.

Laterally between the selector device 20 and the otp capacitor 40, an isolation dielectric 60 is arranged. It covers the drift region 27 partly and encloses the otp capacitor dielectric 50 (see FIG. 1c). In the example shown, the isolation dielectric is a LOCOS structure, i.e. obtained from local oxidation of silicon. By way of example, it may have a thickness tᵢₛₒ of around 350 nm.

FIG. 1b shows an enlarged view (see the dashed line in FIG. 1a) and illustrates the capacitor dielectric 50 in further detail. The capacitor dielectric 50 comprises a first dielectric 51 with a first thickness t₁ and a second dielectric 52 with a second thickness t₂, wherein the first thickness t₁ is smaller than the second thickness t₂. In the example shown, the second thickness t₂ is around two times the first thickness t₁ (t₁ being for instance 2.5 nm and t₂ being 5 nm). As discussed in the general description, the thinner dielectric embedded into the thicker dielectric can for instance improve a programming quality, e.g. provide for a reliable dielectric breakdown. In the embodiment shown, the first capacitor electrode 41 is a doped region 126 in the semiconductor body 30, wherein the doped region 126 also forms the drain region 26 of the selector device 20.

FIG. 1c illustrates the otp cell 10 of FIG. 1a in a vertical top view. Generally, in this disclosure, the like reference numeral indicates the like element or elements having the like function and reference is respectively made to the description of the other figures as well. The gate electrode 22 covers the selector device 20 widely, on the left a body implant of the body region 21 and a source region 25 are visible.

Below the second capacitor electrode 42 of the otp capacitor 40, the capacitor dielectric 50 is arranged (shown in dashed lines). The first dielectric 51 is arranged in a first area 71 and the second dielectric 52 is arranged in a second area 72. The first dielectric 51 is delimited by the second dielectric 52 on all lateral sides. In the example shown, the first area 71 is arranged rather centrally in the second area 72, e.g. a centroid 72.1 of the second area 72 lying in the first area 71. The isolation dielectric 60 is arranged in a third area 73, into which the capacitor dielectric 50 is embedded.

The sectional planes of FIGS. 1a, b lie parallel to a length direction 80, which is a direction of current flow in the channel region (not referenced in FIG. 1c). The channel region is covered by the gate electrode 22, a lateral extension 86 of the channel region is referenced for illustration.

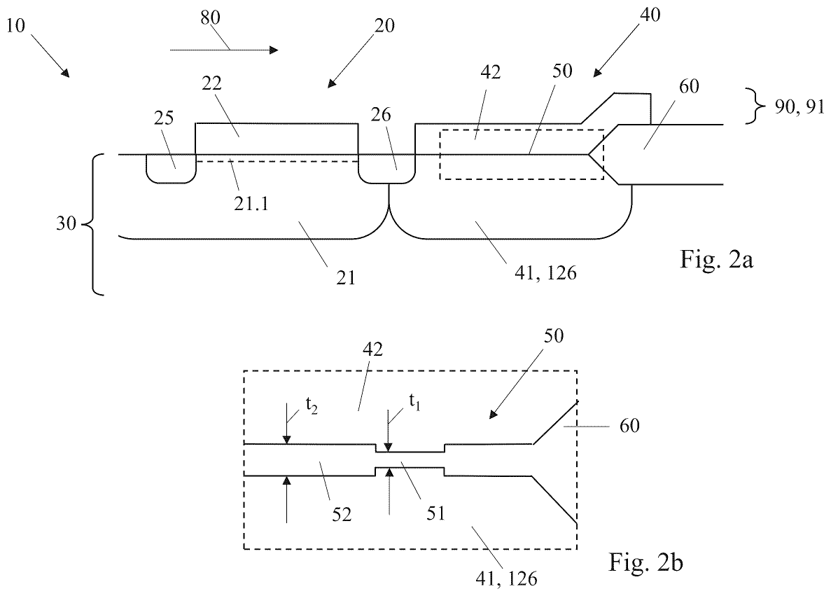

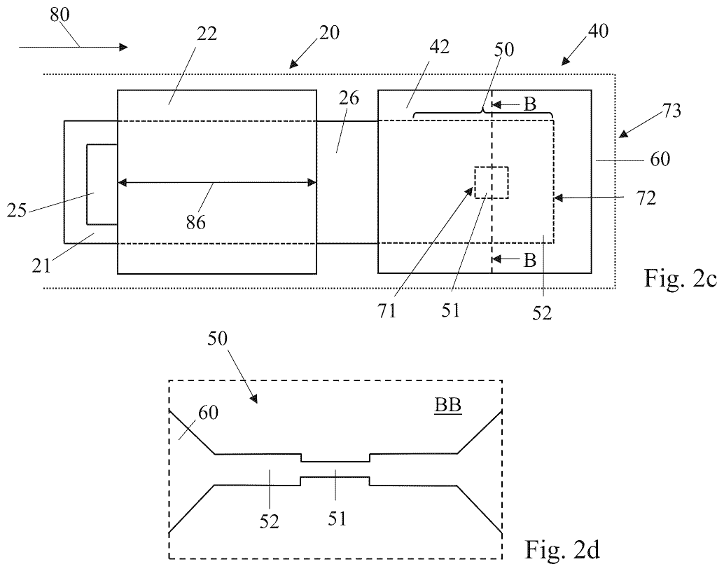

FIG. 2a illustrates another otp cell 10 with a selector device 20 and an otp capacitor 40. As in the embodiment of FIG. 1a, the first capacitor electrode 41 is a doped region 126 embedded into the semiconductor body 30. However, the drain region 26 of the selector device 20 is a separate doping region, the otp capacitor 40 is connected in series to the drain region 26, e.g. to the selector device 20. The doped region 126 may be of the same doping type like the drain region 26, for instance n-doped, but have a lower doping concentration.

As in the example of FIG. 1a, the gate electrode 22 of the selector device and the second capacitor electrode 42 are formed in the same material layer 90, in the example shown in a polysilicon layer 91. Nonetheless, the gate electrode 22 and second capacitor electrode 42 are electrically isolated from each other and may be connected as wordline and bitline.

A difference between the embodiments of FIGS. 1a and 2a is in the arrangement of the isolation dielectric 60, in FIG. 2a it is not provided between the channel region 21.1 and the otp capacitor 40. In the length direction 80, the second dielectric 52 merges only on one side directly into the isolation dielectric 60, namely in the detailed view of FIG. 2b on the right. Apart from that, the otp capacitor dielectric 50 comprises the first dielectric 51 and second dielectric 52 with different thicknesses t₁, t₂, as discussed in detail for FIG. 1b.

As indicated in the vertical top view in FIG. 2c, the lateral extension 86 of the channel region (channel region not referenced in FIG. 2c) corresponds to the extension of the gate electrode 22 in the length direction 80. Between the gate electrode 22 and the second capacitor electrode 42, the drain region 26 of the selector device 20 is visible. The otp capacitor dielectric 50 is arranged below second capacitor electrode 42, it comprises the first dielectric 51 in the first area 71 and the second dielectric 52 in the second area 72. In contrast to the embodiment of FIG. 1a, c, the third area 73 with the isolation dielectric 60 extends only U-shaped around the otp capacitor dielectric 50 (see also sectional view of FIG. 2b).

FIG. 2d shows another sectional view of the capacitor dielectric 50, wherein the sectional plane lies perpendicular to the length direction 80 (see BB in FIG. 2c for comparison). In the sectional view of FIG. 2d, the second dielectric 52 merges directly into the isolation dielectric 60 on both sides.

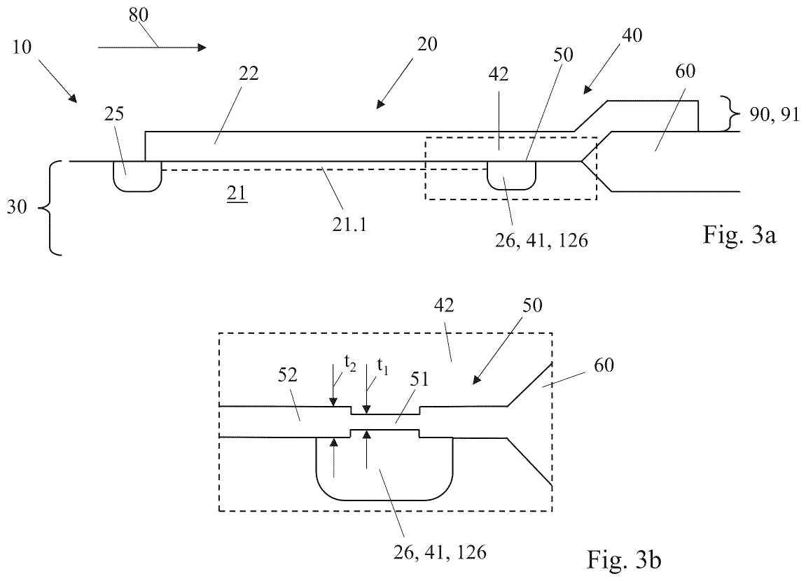

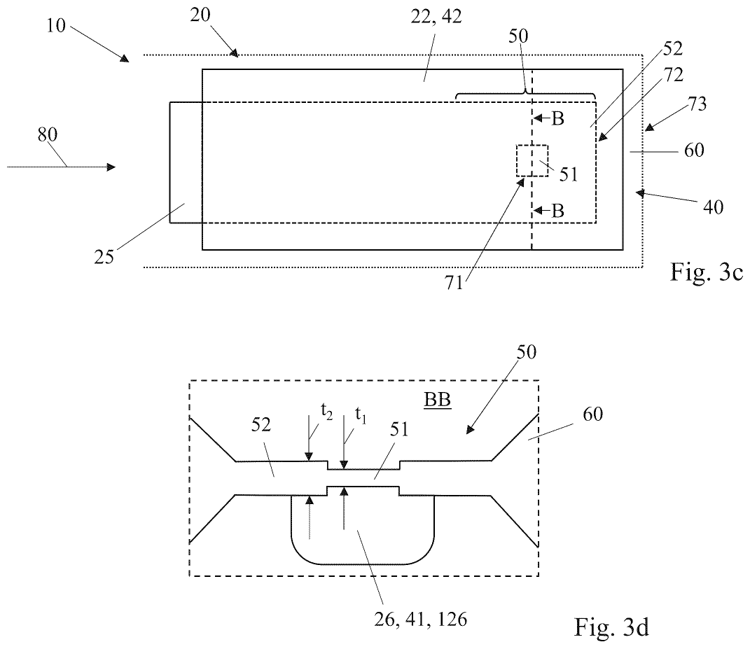

FIG. 3a illustrates another otp cell 10 with a selector device 20 and an otp capacitor 40. The channel region 21.1 formed in the body region 21 extends between the source region 25 and drain region 26, the latter serving also as the first capacitor electrode 41. The channel region 21.1 reaches below the capacitor dielectric 50, see FIGS. 3a and 3b in comparison. In contrast to the embodiments above, the second capacitor electrode 42 is formed integrally with the gate electrode 22. In other words, the second capacitor electrode 42 also serves as the gate electrode 22 of the selector device 20. In the example shown, one continuous polysilicon plate is provided for the selector device 20 and the otp capacitor 40.

FIG. 3b shows a detailed view of the otp capacitor dielectric 50 in a sectional plane parallel to the length direction 80, see the remarks on FIGS. 1b and 2b. Only on one side, namely on the right in FIG. 3b, the second dielectric 52 merges directly into the isolation dielectric 60.

The vertical top view of FIG. 3c illustrates the first area 71 embedded into the second area 72, wherein the third area 73 with the isolation dielectric 60 encloses the otp capacitor dielectric 50 U-shaped, see the remarks in FIG. 2c. In the vertical cross-section perpendicular to the length direction 80, the second dielectric 52 merges on both sides into the isolation dielectric 60, see FIG. 3d.

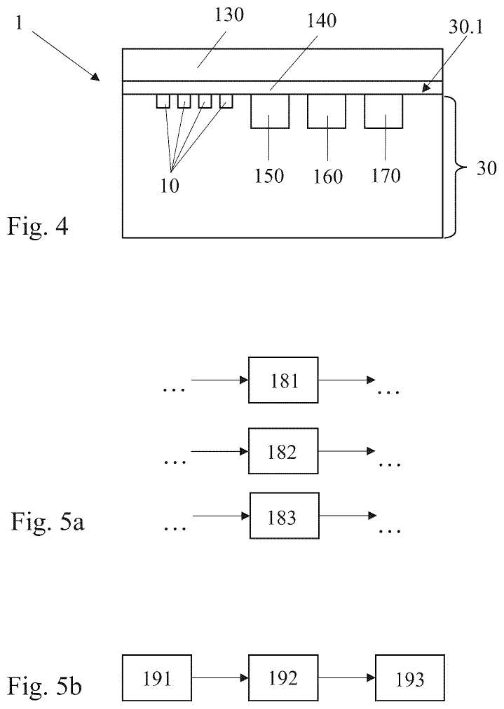

FIG. 4 schematically illustrates an integration of a plurality of otp cells 10 in a semiconductor die 1. The otp cells 10 are arranged at a first side 30.1 of the semiconductor body 30, wherein a metallization system 130 provided for wiring is arranged on an insulating layer 140 on the first side 30.1 of the semiconductor body 30. The metallization system 130 may comprise one or a plurality of metallization layers, but is only shown schematically. For a connection to the individual structures formed in the semiconductor body 30, vertical interconnects extending through the insulating layer 140 may be provided, which are not shown in detail here.

Together with the otp cells 10, a DMOS device 150 and/or a CMOS device 160 and/or a bipolar device 170 may be provided. The DMOS device 150 may serve for a load switching, for instance in combination with a lateral or vertical current routing, for example via sinker implants (not shown). The CMOS device 170 may allow for an integration of logic functions and/or the bipolar device 170 may be used for protection structures.

FIG. 5a summarizes some manufacturing steps, e.g. illustrates a forming 181 of the selector device 20, a forming 182 of the otp capacitor 40 with the otp capacitor dielectric 50, and a forming 183 of the isolation dielectric 60. These steps may be done simultaneously, at least to some extent.

FIG. 5b summarizes some method steps for programming an otp cell or cells 10. It comprises providing 191 a plurality of otp cells 10, selecting 192 at least one otp cell 10 that has to be programmed (permanently switched into a conductive state), and causing 193 a breakdown of the otp capacitor dielectric 50 of the respective cell or cells 10 by a control pulse.

Embodiments and features of the application can be summarized in the form of the following examples. Example 1: a one-time programmable (otp) cell (10), comprising: a selector device (20) with a channel region (21.1); an otp capacitor (40) with an otp capacitor dielectric (50) associated with the selector device (20); and an isolation dielectric (60) having an isolation dielectric thickness tᵢₛₒ, the otp capacitor dielectric (50) comprising a first dielectric (51) in a first area (71) and a second dielectric (52) in a second area (72), the second dielectric (52) having a second thickness t₂ which is smaller than the isolation dielectric thickness tᵢₛₒ, and the first dielectric (51) having a first thickness t₁ which is smaller than the second thickness t₂, wherein the first area (71) is embedded into the second area (72).

Example 2. The otp cell (10) of example 1, wherein the second dielectric (52), as viewed in a vertical cross-section through the first dielectric (51) and parallel to a length direction (80) of the channel region (21.1), merges directly into the isolation dielectric (60) on at least one side.

Example 3. The otp cell (10) of example 1 or 2, wherein the second dielectric (52), as viewed in a vertical cross-section through the first dielectric (51) and perpendicular to a length direction (80) of the channel region (21.1), merges directly into the isolation dielectric (60) on both sides.

Example 4. The otp cell (10) of any one of the preceding examples, wherein the second thickness t₂ is at least 1.5 times and/or at most 20 times the first thickness t₁.

Example 5. The otp cell (10) of any one of the preceding examples, wherein the isolation dielectric thickness tᵢₛₒ is at least 10 times and/or at most 100 times the second thickness t₂.

Example 6. The otp cell (10) of any one of the preceding examples, with at least one of: the first thickness t₁ being at least 1.5 nm and/or at most 5 nm, the second thickness t₂ being at least 4 nm and/or at most 30 nm, and the isolation dielectric thickness tᵢₛₒ being at least 100 nm and/or at most 900 nm.

Example 7. The otp cell (10) of any one of the preceding examples, the selector device (20) comprising a gate electrode (22) and a gate dielectric (23) which capacitively couples the gate electrode (22) to the channel region (21.1), wherein the gate dielectric (23) has the same thickness like the second dielectric (52).

Example 8. The otp cell (10) of any one of the preceding examples, wherein, seen in vertical top view, a centroid (72.1) of the second area (72) lies in the first area (71).

Example 9. The otp cell (10) of any one of the preceding examples, wherein the first area (71) has an area ratio to the second area (72) of at least 1/100 and/or at most 3/4.

Example 10. The otp cell (10) of any one of the preceding examples, the otp capacitor (40) comprising a first capacitor electrode (41) below the otp capacitor dielectric (50), wherein the first capacitor electrode (41) is a doped region (126) embedded into a semiconductor body (30).

Example 11. The otp cell (10) of any one of the preceding examples, the otp capacitor (40) comprising a second capacitor electrode (42) on the otp capacitor dielectric (50), wherein the channel region (21.1) reaches below the otp capacitor dielectric (50) and the second capacitor electrode (42) also serves as a gate electrode (22) of the selector device (20).

Example 12. The otp cell (10) of any one of examples 1 to 10, the selector device (20) comprising a source region (25), a body region (21) and a drain region (26), the channel region (21.1) formed in the body region (21) laterally between the source region (25) and the drain region (26).

Example 13. The otp cell (10) of example 12 in combination with one of examples 1 to 10, wherein a second capacitor electrode (42) of the otp capacitor (40) and a gate electrode (22) of the selector device (20) are formed in the same material layer (90), for example polysilicon layer (91), and are electrically isolated from each other.

Example 14. The otp cell (10) of any one of the preceding examples, the selector device (20) additionally comprising a drift region (27).

Example 15. The otp cell (10) of example 14, wherein the isolation dielectric (60) covers at least a portion of the drift region (27), the second area (72) being embedded into a third area (73) made of the isolation dielectric (60).

Example 16. The opt cell (10) of examples 10 and 12, optionally in combination with one of examples 13 to 15, wherein the drain region (26) of the selector device (20) serves as the first capacitor electrode (41) below the otp capacitor dielectric (50).

Example 17. The opt cell (10) of example 12, optionally in combination with one of examples 13 to 16, wherein the drain region (26) of the selector device (20) is arranged laterally aside and electrically connected in series to a first capacitor electrode (41) below the otp capacitor dielectric (50).

Example 18. A semiconductor die (1), comprising: the otp cell (10) of any one of the preceding examples; and at least one of a DMOS device (150), a CMOS device (160) or a bipolar device (170).

Example 19. The semiconductor die (1) of example 18, wherein a gate dielectric (23) of the selector device (20) and a gate dielectric of the DMOS device (150) have the same thickness.

Example 20. A method of manufacturing the otp cell (10) of any one of examples 1 to 17 or the semiconductor die (1) of example 18 or 19, the method comprising: forming (181) the selector device (20); forming (182) the otp capacitor (40) with the otp capacitor dielectric (50); and forming (183) the isolation dielectric (60).

Example 21. A method of programming a plurality of otp cells (10) according to any one of examples 1 to 17, for example in a semiconductor die (1) of example 18 or 19, the method comprising: causing a breakdown of the otp capacitor dielectric (50) for at least one of the otp cells (10) by a control pulse.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A one-time programmable (otp) cell, comprising:
a selector device with a channel region;
an otp capacitor with an otp capacitor dielectric associated with the selector device; and
an isolation dielectric having an isolation dielectric thickness,
wherein the otp capacitor dielectric comprises a first dielectric in a first area and a second dielectric in a second area,
wherein the second dielectric has a second thickness which is smaller than the isolation dielectric thickness,
wherein the first dielectric has a first thickness which is smaller than the second thickness,
wherein the first area is embedded into the second area.

2. The otp cell of claim 1, wherein the second dielectric, as viewed in a vertical cross-section through the first dielectric and parallel to a length direction of the channel region, merges directly into the isolation dielectric on at least one side.

3. The otp cell of claim 1, wherein the second dielectric, as viewed in a vertical cross-section through the first dielectric and perpendicular to a length direction of the channel region, merges directly into the isolation dielectric on both sides.

4. The otp cell of claim 1, wherein the second thickness is at least 1.5 times and/or at most 20 times the first thickness.

5. The otp cell of claim 1, wherein the isolation dielectric thickness is at least 10 times and/or at most 100 times the second thickness.

6. The otp cell of claim 1, wherein at least one of:
the first thickness is at least 1.5 nm and/or at most 5 nm;
the second thickness is at least 4 nm and/or at most 30 nm; and
the isolation dielectric thickness is at least 100 nm and/or at most 900 nm.

7. The otp cell of claim 1, wherein the selector device comprises a gate electrode and a gate dielectric which capacitively couples the gate electrode to the channel region, and wherein the gate dielectric has a same thickness as the second dielectric.

8. The otp cell of claim 1, wherein in a vertical top view, a centroid of the second area lies in the first area.

9. The otp cell of claim 1, wherein the first area has an area ratio to the second area of at least 1/100 and/or at most 3/4.

10. The otp cell of claim 1, wherein the otp capacitor comprises a first capacitor electrode below the otp capacitor dielectric, and wherein the first capacitor electrode is a doped region embedded into a semiconductor body.

11. The otp cell of claim 1, wherein the otp capacitor comprises a second capacitor electrode on the otp capacitor dielectric, wherein the channel region reaches below the otp capacitor dielectric, and wherein the second capacitor electrode serves as a gate electrode of the selector device.

12. The otp cell of claim 1, wherein the selector device comprises a source region, a body region, and a drain region, and wherein the channel region is formed in the body region laterally between the source region and the drain region.

13. The otp cell of claim 12, wherein a second capacitor electrode of the otp capacitor and a gate electrode of the selector device are formed in a same material layer and are electrically isolated from each other.

14. The opt cell of claim 12, wherein the drain region of the selector device is arranged laterally aside and electrically connected in series to a first capacitor electrode below the otp capacitor dielectric.

15. The otp cell of claim 1, wherein the selector device comprises a drift region.

16. The otp cell of claim 15, wherein the isolation dielectric covers at least a portion of the drift region, and wherein the second area is embedded into a third area made of the isolation dielectric.

17. The opt cell of claim 1, wherein the otp capacitor comprises a first capacitor electrode below the otp capacitor dielectric, wherein the first capacitor electrode is a doped region embedded into a semiconductor body, wherein the selector device comprises a source region, a body region, and a drain region, wherein the channel region is formed in the body region laterally between the source region and the drain region, and wherein the drain region of the selector device serves as the first capacitor electrode below the otp capacitor dielectric.

18. A semiconductor die, comprising:
the otp cell of claim 1; and
at least one of a DMOS device, a CMOS device, or a bipolar device.

19. The semiconductor die of claim 18, wherein a gate dielectric of the selector device and a gate dielectric of the DMOS device have a same thickness.

20. A method of manufacturing a one-time programmable (otp) cell, the method comprising:
forming a selector device with a channel region;
forming an otp capacitor with an otp capacitor dielectric associated with the selector device; and
forming an isolation dielectric having an isolation dielectric thickness,
wherein the otp capacitor dielectric comprises a first dielectric in a first area and a second dielectric in a second area,
wherein the second dielectric has a second thickness which is smaller than the isolation dielectric thickness,
wherein the first dielectric has a first thickness which is smaller than the second thickness,
wherein the first area is embedded into the second area.

21. A method of programming a one-time programmable cell that includes a selector device with a channel region, an otp capacitor with an otp capacitor dielectric associated with the selector device, and an isolation dielectric having an isolation dielectric thickness, the otp capacitor dielectric comprising a first dielectric in a first area and a second dielectric in a second area, the second dielectric having a second thickness which is smaller than the isolation dielectric thickness, the first dielectric having a first thickness which is smaller than the second thickness, the first area being embedded into the second area, the method comprising:
applying a control pulse to the otp capacitor dielectric via the selector device; and
causing a breakdown of the otp capacitor dielectric by the control pulse.
